(19) United States
(12) Patent Application Publication
(10) Pub. No.: US 2025/0208398 A1
(43) Pub. Date: Jun. 26, 2025

(54) MAGNIFYING IMAGING OPTICAL UNIT FOR A METROLOGY SYSTEM FOR EXAMINING OBJECTS

(71) Applicant: Carl Zeiss SMT GmbH, Oberkochen (DE)

(72) Inventors: Dirk Döring, Erfurt (DE); Michael Gölles, Jena (DE); Torsten Antrack, Aalen (DE); Alexander Epple, Aalen (DE); Helmut Körner, Heidenheim a.d. Brenz (DE); Sascha Perlitz, Jena (DE); Ulrich Matejka, Jena (DE); Lutz Reichmann, Jena (DE); Olaf Rogalsky, Ulm (DE); Sören Schmidt, Jena (DE)

(21) Appl. No.: 18/983,898

(22) Filed: Dec. 17, 2024

(30) Foreign Application Priority Data
Dec. 22, 2023 (DE) 102023213267.2

(51) Int. Cl. G02B 21/04; G02B 21/00

(52) U.S. Cl. CPC G02B 21/04; G02B 21/0032; G02B 21/0052

(57) ABSTRACT

A magnifying imaging optical unit is part of a metrology system for examining objects. The magnifying imaging optical unit has at most four mirrors which image an object field in an object plane into an image field in an image plane. According to one aspect, an entrance pupil of the magnifying imaging optical unit has a boundary shape which deviates from an ellipse and the aspect ratio of which is not equal to 1. In accordance with a further aspect, reflection surfaces of small-area mirrors which are used for guiding imaging light along an imaging beam path deviate from a spherical shape by at most 10 μm. This results in a magnifying imaging optical unit in which an imaging result which satisfies the stringent requirements of a metrology system results for a given manufacturing outlay.

### CROSS-REFERENCE TO RELATED APPLICATION

The content of the German Patent Application DE 10 2023 213 267.2, filed on Dec. 22, 2023, is incorporated by reference herein in its entirety.

### TECHNICAL FIELD

The invention relates to a magnifying imaging optical unit for a metrology system for examining objects. Furthermore, the invention relates to an illumination optical unit for a metrology system, adapted to such an imaging optical unit, an optical system comprising such an imaging optical unit and an illumination optical unit, and also a metrology system comprising such an optical system.

### BACKGROUND

A mask inspection system is known from U.S. Pat. No. 8,842,284, from US 2013/0250428 A1, from WO 2016/012426 A1, from U.S. Pat. No. 10,042,248 B2, from DE 102 20 815 A1 and from WO 2012/101269 A1. DE 10 2010 029 050 A1 and DE 10 2011 084 255 A1 each disclose a magnifying imaging optical unit and also a metrology system comprising such an imaging optical unit. DE 10 2010 029 049 A1 discloses an illumination system for a metrology system and also a metrology system comprising such an illumination optical unit.

### SUMMARY

It is a general aspect of the present invention to develop a magnifying imaging optical unit in such a way that a good imaging result which satisfies the stringent requirements of a metrology system results for a given manufacturing outlay.

According to a first aspect, this general aspect is achieved according to the invention by a magnifying imaging optical unit according to Claim 1.

According to the invention, it has been recognized that a non-elliptic entrance pupil with an aspect ratio not equal to 1 affords additional possibilities for adapting guidance of the imaging beam path within the magnifying imaging optical unit in particular to a beam path of illumination light which illuminates the object field, and this can improve an imaging quality and/or a light throughput of the imaging optical unit. The boundary shape of the entrance pupil can be adapted to imaging requirements, for example to different typical object structure sizes in two mutually perpendicular field dimensions. Alternatively or additionally, an adaptation to a diffraction effect of the object structures and/or else to an illumination pupil of an illumination optical unit of the metrology system is possible, which for its part has a boundary shape with an aspect ratio not equal to 1.

An x:y aspect ratio of the entrance pupil of the magnifying imaging optical unit can be in the range of between 1.1:1 and 5:1, wherein the x-coordinate here can be perpendicular to a meridional plane of the magnifying imaging optical unit. The x:y aspect ratio can be 2:1, for example.

Having at most four mirrors, the magnifying imaging optical unit exhibits a good compromise between total reflectivity, in particular when used with EUV wavelengths, and corrected imaging.

A smallest resultant object-side numerical aperture of the magnifying imaging optical unit can be greater than 0.1, can be greater than 0.12 and can be for example 0.125 or else 0.135.

A boundary shape of the entrance pupil according to Claim 2 can be adapted well to structural requirements and in particular to spatial requirements of the imaging beam path. This results in a correspondingly high light throughput.

The same correspondingly applies to an entrance pupil comprising a cutout portion according to Claim 3. The cutout portion can take account of an obscuration by at least one mirror of the magnifying imaging optical unit.

Advantages of an entrance pupil with an aspect ratio not equal to 1 are manifested particularly well in the case of a configuration according to Claim 4. The at least one mirror whose boundary corresponds to that of the entrance pupil can be a near-pupil mirror. This can involve the first mirror and optionally also the second mirror of the magnifying imaging optical unit.

According to a further aspect, the object mentioned in the introduction is achieved according to the invention by a magnifying imaging optical unit having the features specified in Claim 5.

According to the invention, it has been recognized that, without unwanted reductions in an imaging quality, it is possible to embody the magnifying imaging optical unit with small-area mirrors which deviate from a spherical shape only slightly or even not at all. This facilitates production of the small-area mirrors of the magnifying imaging optical unit and affords corresponding manufacturing advantages. This in particular is true for reflection surface diameters which are less than 50 mm.

The deviation of the reflection surfaces from a spherical shape is measured in relation to a spherical shape which is best fitted to the respective mirror reflection surface. Such a best fit can be determined by square error minimization upon comparing the respective reflection surface with a spherical surface. A deviation of the reflection surface of the small-area mirror from a spherical surface by at most 10 μm facilitates the manufacturing of such mirror. In particular, in that case as a rule measuring instruments to ensure correct production of the reflection surface need not to be altered as compared to a measurement of a spherical shape.

The deviation of the reflection surface of the respective small-area mirror from the spherical shape can be at most 5 μm, or can also be at most 1 μm. Such a small deviation enables processing during mirror production with a small number of processing cycles. The small-area mirror can be embodied as a nanoasphere in which a deviation of the reflection surface from a spherical shape amounts to at most ten times the used wavelength. Such a nanoasphere can be measured by a measuring technique designed for measuring a spherical reflection surface.

An intermediate image can be situated between a first and a second mirror in the imaging beam path of the magnifying imaging optical unit. Said intermediate image can be used for improving an imaging aberration-correcting effect. Moreover, this can be used to create an especially compact beam path in the region of the mirrors arranged near the intermediate focus or near-field.

A parameter P defined in WO 2009/024164 A1, the entire content of which is incorporated by reference, can be used for characterizing such a property “near-field”. A mirror is deemed to be near-field if the parameter P is less than 0.5 and in particular is less than 0.4, less than 0.3, less than 0.25, or else less than 0.2. For real mirrors this parameter P is regularly greater than 0.05.

A last mirror of the magnifying imaging optical unit in the imaging beam path can be embodied as near-field.

A first and optionally also a second mirror in the imaging beam path of the magnifying imaging optical unit can be embodied as near-pupil. For these near-pupil mirrors the parameter P is greater than 0.5, can be greater than 0.6, can be greater than 0.7 and can also be greater than 0.8. For a real near-pupil mirror the parameter P is regularly less than 0.95.

The magnifying imaging optical unit can be designed for use with EUV imaging light in particular having a wavelength which is in the range of between 5 nm and 30 nm, and is for example 13.5 nm. The magnifying imaging optical unit can have highly reflective coatings embodied for corresponding EUV wavelengths, in particular.

A structural length of the magnifying imaging optical unit can be at most 1250 mm, which results in a compact optical unit.

The mirrors of the magnifying imaging optical unit can be embodied such that none of the mirrors has a diameter of a reflection surface used for guiding the imaging light along the imaging beam path which is greater than 400 mm. This, too, results in a compact optical unit.

In the case of an embodiment according to Claim 6, the reflection surfaces of all the mirrors deviate only slightly, namely by at most 25 μm, from a spherical shape, i.e. even from mirrors having a diameter which is at least 50 mm, which hereinafter are also referred to as large-area mirrors. This results in corresponding manufacturing advantages for all the mirrors of the magnifying imaging optical unit. The deviation of the reflection surface mirrors from the spherical shape can be at most 20 μm, at most 15 μm, or for all the mirrors can also be of the same magnitude as discussed above in connection with the at least one small-area mirror.

The features of the magnifying imaging optical units in accordance with the two aspects discussed above can also be present in combination with one another.

Distance ratios according to Claim 7 have the consequence that imperfections and/or contaminations on the last mirror in the imaging beam path of the magnifying imaging optical unit do not have any unwanted effects on an imaging quality of the optical unit. This holds true particularly if the last mirror is embodied as a near-field mirror. The distance between the last mirror and the image plane can be greater than 65% of a distance between the object plane and the image plane. This distance is regularly smaller than the distance between the object plane and the image plane.

A distance between the last mirror and an antepenultimate mirror in the imaging beam path of the magnifying imaging optical unit along a coordinate perpendicular to the image plane, assuming a corresponding embodiment of the magnifying imaging optical unit, can be less than 15%, less than 12% or else less than 10% of the distance between the object plane and the image plane. This distance between the last and antepenultimate mirrors is regularly greater than 1% of the distance between the object plane and the image plane.

A magnification ratio according to Claim 8 has proved worthwhile in practice. Such a magnification ratio can be adapted to pixel sizes of a spatially resolving detection device of the metrology system which captures the image field.

The magnifying imaging optical unit can have an object field having an extent in the two object field dimensions in the range of in each case between 0.1 mm and 1 mm and can have an area of 0.1 mm² to 0.5 mm², for example. A typical object field extent is 0.3 mm×0.6 mm or else 0.5 mm×0.5 mm.

Angles of incidence according to Claims 9 and 10 have proved worthwhile in practice and result in advantageous reflection conditions or in good imaging conditions. An angle of incidence on the mirrors can be in each case at most 13° or else even smaller. The lower such angle value is, the lower is an effect of angular variations which helps to provide well-suited reflection coatings on such mirrors.

An RMS wavefront aberration according to Claim 11 results in a good imaging quality. An image field-side Petzval radius of the magnifying imaging optical unit can be greater than 500 mm.

A minimum value for a deviation of a mirror reflection surface from a spherical shape according to Claim 12 has proved worthwhile in practice. At a used wavelength of 13.5 nm, this corresponds to a minimum deviation, i.e. a deviation lower limit, of 25 nm. Depending on the embodiment of the magnifying imaging optical unit, a plurality of mirrors, for example two or three mirrors, can satisfy this criterion of the deviation lower limit, or else exactly one of the mirrors. In a further embodiment, all the mirrors of the magnifying imaging optical unit satisfy this deviation lower limit of double the used wavelength. Such lower boundary for the reflection surface deviation from a spherical shape ensures a desired beam shaping effect of the resulting mirror.

The advantages of an illumination optical unit according to Claim 13 correspond to those which have already been explained above in connection with the various aspects of the magnifying imaging optical unit.

A boundary shape of the illumination pupil can be at least approximately elliptic, can be at least approximately stadium-shaped and can also be at least approximately semicircular.

The advantages of an optical system according to Claim 14 or 15 and of a metrology system according to Claim 16 correspond to those which have already been explained above with reference to the magnifying imaging optical unit and the illumination optical unit.

The light source of the metrology system can be an EUV light source.

The detection device can have at least one time delay integration (TDI) camera.

The metrology system can be embodied as a mask inspection system or else as a wafer inspection system.

The inspection system can comprise an object holder serving to hold the object to be inspected and mechanically coupled to an object displacement drive so that a scanning displacement of the object is possible during the illumination.

The inspection system can be a system for actinic mask or wafer inspection.

### BRIEF DESCRIPTION OF THE DRAWINGS

One exemplary embodiment of the invention is explained in greater detail below with reference to the drawing, in which:

FIG. 1 schematically shows, in a meridional section, a mask inspection system for lithography masks for use with EUV illumination light, comprising an illumination system, having an energy detection assembly comprising a beam-homogenizing element, comprising an imaging optical unit and comprising at least one EUV energy sensor device;

FIG. 2 shows, in a meridional section, a schematic view of a further embodiment of an imaging optical unit which can be used in the mask inspection system instead of the imaging optical unit according to FIG. 1;

FIG. 3 shows a schematic view of the imaging optical unit from viewing direction III in FIG. 2;

FIG. 4 shows, in a meridional section, a further embodiment of an imaging optical unit which can be used in the mask inspection system instead of the imaging optical unit according to FIG. 1;

FIG. 5 shows, in pupil coordinates, an entrance pupil of the imaging optical unit according to FIG. 4;

FIG. 6 shows, in a meridional section, an embodiment of an imaging optical unit which can be used in the mask inspection system instead of the imaging optical unit according to FIG. 1; and

FIG. 7 shows, in pupil coordinates, an entrance pupil of the imaging optical unit according to FIG. 6.

### DETAILED DESCRIPTION

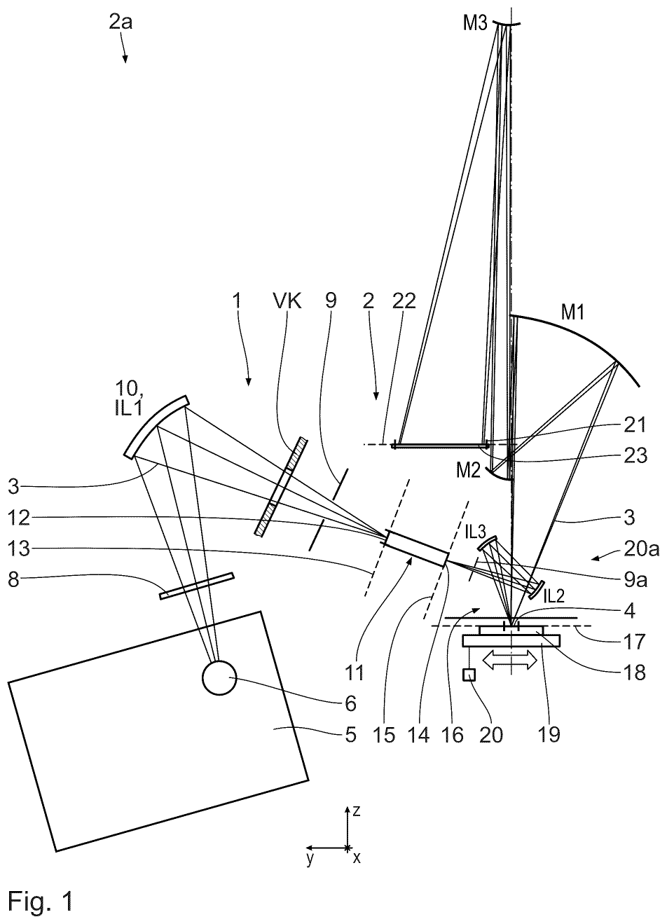

An illumination optical unit 1 is a constituent part of an optical system 2 of a mask inspection system 2a for use with EUV illumination light 3. A beam path of the illumination light 3 is illustrated by way of marginal rays and a chief ray for the illumination optical unit 1 in FIG. 1. An illumination field 4 of the mask inspection system is illuminated by the illumination light 3.

The illumination light 3 is generated by an EUV light source 5 into a source region 6. The light source 5 can generate EUV used radiation in a wavelength range of between 2 nm and 30 nm, for example in the range of between 2.3 nm and 4.4 nm or in the range of between 5 nm and 30 nm, for example at 13.5 nm.

The light source 5 is embodied as a plasma light source. By way of example, this can be a laser plasma source (LPP; laser produced plasma) or else a discharge source (DPP; discharge produced plasma). In principle, such plasma sources are known as light sources for EUV projection exposure apparatuses. Alternatively, the light source 5 can also be embodied as a high-harmonic EUV source. A pulse frequency of the light source 5 can be in the kHz range.

In order to facilitate positional relationships, a Cartesian xyz-coordinate system will be used hereinafter. The x-axis is perpendicular to the plane of the drawing in FIG. 1 and runs into the latter. The y-axis runs horizontally towards the left in FIG. 1, and the z-axis runs vertically upwards in FIG. 1.

After emission by the light source 5, the illumination light 3 firstly passes through a used light filter 8 arranged in an operating position in the beam path of the illumination light 3 between the source volume 6 and a first ellipsoidal mirror IL1 of the illumination optical unit 1. The used light filter 8 can be a filter from a plurality of filters kept available for example in a filter magazine at the metrology system 2a. A further used light filter can be arranged in a waiting position outside the illumination light beam path of the illumination optical unit 1. The used light filters 8 can have the same transmission characteristic, in which case a changeover between the used light filters can be effected if a degradation of a filter effect of the operating used light filter 8 is ascertained. Alternatively, the used light filters can also have different filter characteristics and for example can transmit different used light wavelength ranges into the downstream illumination light beam path or be optimized for filtering out different extraneous light components.

The used light filters can be embodied in such a way that they filter out in particular pump light which is concomitantly guided in the illumination light beam path and which was used during the generation of used light in the source volume 6.

Downstream of the filter 8 and the mirror IL1, the illumination light 3 firstly passes through an aperture stop 9 which delimits the edge of a beam of the illumination light 3. After that, the illumination light beam 3 is transferred towards a beam-homogenizing element 11 of the illumination optical unit 1. In this case, the mirror IL1 serves as an input coupling optical unit 10 for incoupling the illumination light 3 into the beam-homogenizing element 11.

Between the source volume 6 and the beam-homogenizing element 11, generally downstream of the first mirror IL1 of the illumination optical unit 1, the illumination light 3 passes through an opening in a wall of a vacuum chamber VK, which is indicated between the mirror IL1 and the illumination light aperture stop 9 in the illumination light beam path in FIG. 1.

The aperture stop 9 limits a numerical aperture of the illumination light beam 3 emitted by the source region 6 to a value of the numerical aperture ranging between 0.02 and 0.2, for example ranging between 0.07 and 0.15 or else ranging between 0.05 and 0.08. As an alternative or in addition to the aperture stop 9, an aperture-limiting stop can be arranged between the beam-homogenizing element 11 and a downstream optical component of the illumination optical unit 1 as indicated at 9a in FIG. 1. An arrangement of such a further aperture stop in the beam path of the illumination light 3 downstream of the beam-homogenizing element 11 between two downstream optical components of the illumination optical unit 1 is also possible.

The ellipsoidal mirror IL1 serves to image the source region 6 of the EUV light source 5 into an entrance opening 12 in an entrance plane 13 of the beam-homogenizing element 11. A first focus of the ellipsoidal mirror IL1 is therefore located in the source region 6 and a second focus of the ellipsoidal mirror IL1 is located in the entrance opening 12. The ellipsoidal mirror IL1 is used to focus the illumination light beam 3 into the entrance opening 12 in the entrance plane 13 of the beam-homogenizing element 11. An entrance-side numerical aperture of the illumination light beam 3 upon entrance into the entrance opening 12 can range between 0.02 and 0.2, for example be of the order of 0.05.

An angle of incidence of a central chief ray of the illumination light beam 3 on the input coupling mirror IL1 can range between 10° and 20°. The ellipsoidal mirror IL1 can be a normal incidence (NI) mirror, but can also be embodied as a grazing incidence (GI) mirror.

The entrance opening 12 and an exit opening 14 of the beam-homogenizing element 11 are each square or rectangular with typical dimensions in the range of between 0.5 mm and 5 mm and for example between 0.5 mm and 2 mm or else between 0.5 mm and 1 mm. An aspect ratio of the entrance opening 12 and of an identically sized exit opening 14 of the beam-homogenizing element 11 for the illumination light 3 in an exit plane 15 is between 0.5 and 2. Such aspect ratio is calculated to be the ratio of the dimensions of the larger and the smaller extension of the respective entrance opening 12 or exit opening 14. A typical size of the entrance opening 12 and of the exit opening 14 of the beam-homogenizing element 11 is e.g. 0.5 mm×1.0 mm, 0.75 mm×0.75 mm, 1.0 mm×2.0 mm or 1.5 mm×2.0 mm.

The beam-homogenizing element 11 can be embodied as a hollow waveguide.

The beam-homogenizing element 11 has a typical length perpendicular to the planes 13 and 15, i.e. along a main beam direction of the illumination light 3, in the range of between 50 mm and 500 mm, e.g. in the range of between 50 mm and 150 mm, in particular in the range of between 50 mm and 100 mm.

An angle between a normal to the entrance plane 13 of the beam-homogenizing element 11 and the chief ray of the illumination light beam 3 incident into the entrance opening 12 can be 0° or can alternatively also differ from 0° and for example range between 0° and 1.5°, for example between 0.25° and 0.75°, and in particular be of the order of 0.5°.

A ratio of the distance between the entrance plane 13 and the exit plane 15 and a size or the typical diameter of the entrance opening and respectively the exit opening 12, 14 ranges between 50 and 1000 and can for example range between 50 and 200.

An imaging output coupling mirror optical unit 16 situated downstream of the beam-homogenizing element 11 and having two mirrors IL2, IL3 images the exit opening 14, located in an exit plane 15, of the beam-homogenizing element 11 into the illumination field 4 in an object plane 17. This imaging can have an image-side numerical aperture ranging between 0.05 and 0.2.

In the illustrated embodiment, the output coupling mirror optical unit 16 has exactly two mirrors, namely the mirrors IL2 and IL3. The above-described, optionally used aperture stop downstream of the beam-homogenizing element 11 can be arranged between the beam-homogenizing element 11 and the mirror IL2, or else between the mirrors IL2 and IL3.

The output coupling mirror optical unit 16 is embodied in the style of a Wolter telescope, namely in the style of a Type I Wolter optical unit. Such Wolter optical units are described in J. D. Mangus, J. H. Underwood “Optical Design of a Glancing Incidence X-ray Telescope,” Applied Optics, Vol. 8, 1969, page 95, and the references cited therein. In such Wolter optical units, a hyperboloid can also be used in place of a paraboloid. Such a combination of an ellipsoidal mirror with a hyperboloid mirror also constitutes a Type I Wolter optical unit.

An exemplary embodiment of the output coupling mirror optical unit 16 is described in U.S. Pat. No. 10,042,248 B2.

An imaging factor β₁ of the input coupling mirror optical unit 10 can range between 0.1 and 50, which is to say its action can vary from a reduction by a factor of 10 to a magnification of a factor of 50. An imaging factor β₂ of the output coupling mirror optical unit 16 can range between 0.02 and 10, which is to say its action in turn can vary from a reduction by a factor of 50 to a magnification of a factor of 10. In the case of the illumination optical unit 1, a product β₁, β₂ of the two imaging factors can range between 0.25 and 10.

A reticle 18 to be inspected, which is held by a reticle holder 19, is arranged as object to be inspected or mask to be inspected in the object plane 17. The reticle holder 19 is mechanically operatively connected to a reticle displacement drive 20, by means of which the reticle 18 is displaced along an object displacement direction y during a mask inspection. In this way, a scanning displacement of the reticle 18 in the object plane 17 is rendered possible.

The illumination field 4 has a typical dimension in the object plane 17 which is less than 1.5 mm. In the embodiment illustrated, the extent of the illumination field 4 is, e.g., 1 mm in the x-direction and, e.g., 0.5 mm in the y-direction.

The x/y aspect ratio of the illumination field 4 corresponds to the x/y aspect ratio of the exit opening 14. The x/y aspect ratio of the illumination field 4 is the ratio between the x dimension and the y dimension of the illumination field 4. The x/y aspect ratio of the exit opening 14 is the ratio between the x dimension and the y dimension of the exit opening 14.

The illumination field 4 or a part of the illumination field 4, this part then constituting an object field, is imaged into an image field 21 in an image plane 22 by a projection optical unit 20a. A size of the image field 21 can be in the range of 150 mm×300 mm. The shorter image field extent runs along the scanning direction y.

The projection optical unit 20a has a magnification ratio of the imaging of the object field or illumination field 4 into the image field 21 of 500. Depending on the embodiment of the projection optical unit 20a, said magnification ratio can be in the range of between 250 and 500.

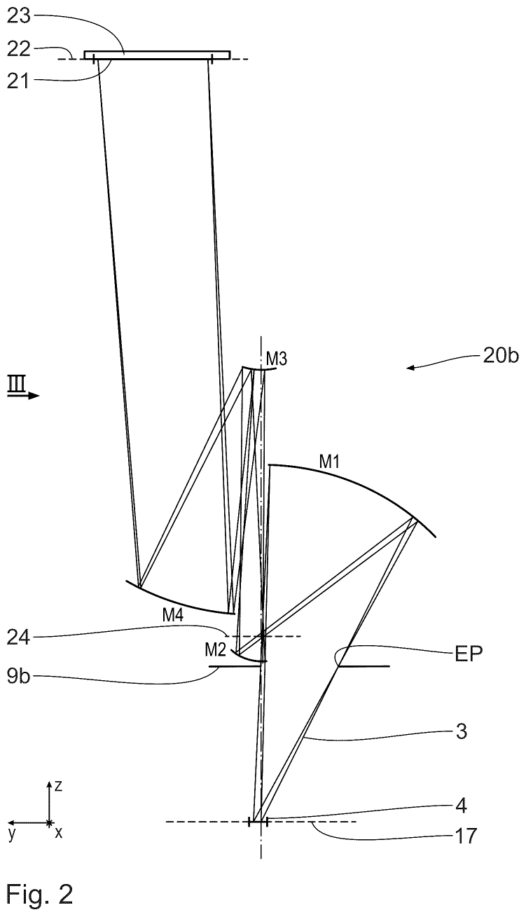

The projection optical unit 20a has mirrors M1, M2, M3 consecutively numbered in the imaging beam path of the projection optical unit 20a, i.e. comprises a total of three mirrors. Depending on the embodiment of the projection optical unit 20a, the number of mirrors can also be greater than three. Further embodiments which can be used instead of the projection optical unit 20a will also be explained below with reference to FIG. 2 et seq.

An aperture stop 9b is arranged in an entrance pupil plane EP of the projection optical unit 20a, which is located between the reflective reticle 18 and the first mirror M1 in the imaging beam path of the illumination or imaging light. Said aperture stop 9b can also serve for predefining an internal obscuration of the projection optical unit 20a that may be present.

The mirrors M1 and M2 of the projection optical unit 20a are embodied as NI mirrors with an angle of incidence of the illumination and imaging light 3 of less than 45°. A maximum angle of incidence of individual rays of the imaging light 3 on the mirrors M1 and M2 is of the order of 14°.

The illumination or imaging light 3 is incident on the image field 21 with an angle of incidence which is less than 5°.

The mirror M1 has a boundary of a reflection surface which is used for guiding the imaging or illumination light 3 along the imaging beam path which corresponds to the boundary of an entrance pupil EP which is predefined by the aperture stop 9b.

At least one of the mirrors M1 and M2 can be embodied as an aspherical mirror. The projection optical unit 20a can have one aspherical mirror or can have two aspherical mirrors.

For its part, the illumination optical unit 1 of the metrology system 2a has an illumination pupil, predefined by way of the aperture stop 9b, which is adapted to the entrance pupil EP. This illumination pupil of the illumination optical unit 1 can have a boundary shape which deviates from an ellipse and the aspect ratio of which is not equal to 1. In that way, a boundary of such illumination pupil exhibits different extreme values of an illumination angle defined by such boundary position, i.e. a maximum boundary illumination angle at the longer semi axis of the ellipse and a minimum boundary illumination angle at the shorter semi axis of the ellipse. A triangle, a square, a rectangle or an arbitrary polygon having extensions in two perpendicular dimensions which have a ratio which is not equal to 1 fulfil the above condition “boundary shape which deviates from an ellipse and having an aspect ratio which is not equal to 1.” The illumination pupil can have an approximately elliptic, an approximately stadium-shaped or else an approximately semicircular boundary shape having a corresponding aspect ratio which deviates from 1. Such “approximately” condition is fulfilled for an illumination pupil area which deviates not more than 20% or 10% from a best fitted ellipse, stadium or semicircle. The aspect ratio of the illumination pupil can correspond to that of the entrance pupil EP of the imaging optical unit 20a.

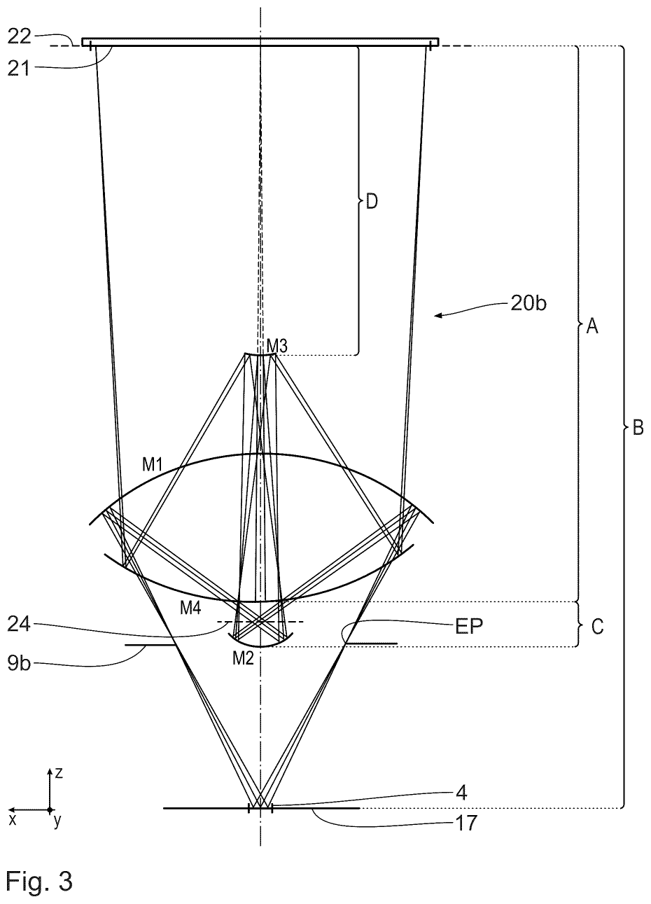

A further embodiment of a projection optical unit 20b, which can be used instead of the projection optical unit 20a in the mask inspection system 2a, is described below with reference to FIGS. 2 and 3. Components and functions corresponding to those which have already been described above with reference to FIG. 1 bear the same reference signs, in particular, and will not be discussed in detail again.

The projection optical unit 20b has a total of 4 mirrors M1, M2, M3 and M4 in the imaging beam path between the object field or illumination field 4 and the image field 21, which mirrors are once again consecutively numbered in the order in which the illumination or imaging light 3 impinges on them. In FIG. 2, the imaging beam path of the projection optical unit 20b is illustrated by marginal rays which emanate from two object field points spaced apart from one another. In the view according to FIG. 3, the number of field points spaced apart from one another is three.

At least one of the mirrors M1 to M4 can be embodied as an aspherical mirror. The projection optical unit 20b can have one aspherical mirror, can have two aspherical mirrors or else can have three aspherical mirrors. It is also the case that all four mirrors of the projection optical unit 20b can be embodied as aspherical.

An entrance pupil plane, in which the aperture stop 9b is arranged, is located between the object field 4 and the mirror M1.

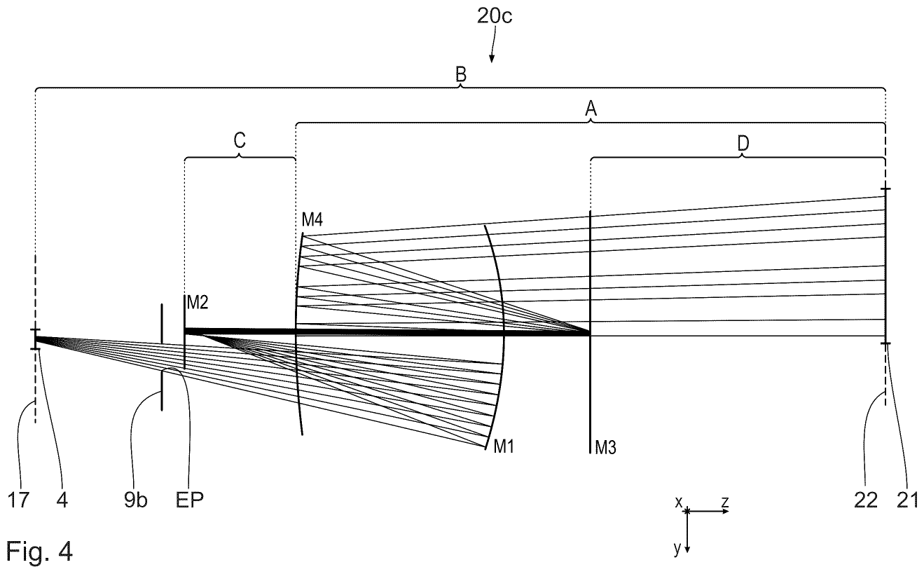

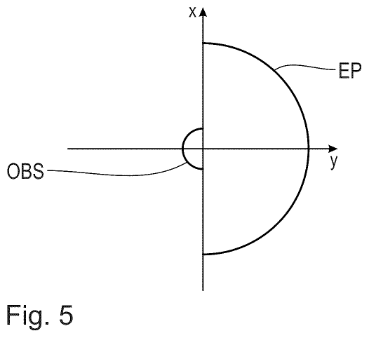

A boundary shape of an entrance pupil EP of the projection optical unit 20b, which is predefined by an inner boundary of the aperture stop 9b, is semicircular and corresponds to the shape of the entrance pupil which will also be explained below in association with the further embodiment of the projection optical units from FIGS. 4 and 5.

A diameter extent of this semicircular shape of the entrance pupil EP runs parallel to the x-coordinate. In the region of a corresponding diameter boundary section through the entrance pupil EP running along the x-coordinate, the entrance pupil EP is delimited by an obscuration caused by the mirror M2.

An x:y aspect ratio of the entrance pupil EP is 2:1 in the case of the projection optical unit 20b. Depending on the embodiment of the projection optical unit 20b, said aspect ratio can be in the range of between 5:1 and 1.1:1. An object-side numerical aperture of the projection optical unit 20b is approximately 0.125 (NAy=0.125) in the yz-plane according to FIG. 2, and approximately 0.25 (NAx=0.25) in the xz-plane perpendicular thereto. Depending on the embodiment of the projection optical unit 20b, the NAx can be between 0.1 and 0.5 and the NAy can be between 0.05 and 0.25.

An intermediate image 24 is located between the mirrors M1 and M2 in the imaging beam path of the projection optical unit 20b.

On the mirrors M1 and M2, individual rays associated with different field points but the same illumination angles are at a comparatively small distance from one another which amounts to at most one quarter of a total used reflection surface diameter of the respective mirror. A parameter P, which characterizes a field or pupil proximity of the respective mirror and is defined in WO 2009/024164 A1, is at a value of P>0.5 for each of the mirrors M1 and M2. The mirrors M1 and M2 are therefore near-pupil. In particular, the mirror M1 is a near-pupil mirror.

On the mirrors M3 and M4, individual rays associated with the same field points but different illumination angles are once again at a distance from one another which amounts to at most one quarter of a total used reflection surface diameter of the respective mirror; the parameter P (cf. once again the definition from WO 2009/024164 A1) is less than 0.5 for each of the mirrors M3 and M4. The mirrors M3 and M4 are therefore mirrors arranged near-field in the imaging beam path of the projection optical unit 20b. In particular, the mirror M4 is a near-field mirror.

A boundary of a reflection surface of the mirror M1 which is used for guiding the imaging light 3 along the imaging beam path corresponds to the boundary of the entrance pupil EP. This approximately applies to the mirror M2 as well. In the case of the mirror M2, a boundary shape is specularly reflected about the xz-plane in comparison with the boundary of the mirror M1 and also in comparison with the boundary of the entrance pupil EP.

A boundary of a reflection surface of the mirror M4 which is used for guiding the imaging light 3 along the imaging beam path corresponds to a boundary of the image field 21, the latter boundary regularly being embodied as rectangular or square. In a similar form, this applies to the mirror M3 as well.

The mirror M4, i.e. the last mirror in the imaging beam path, is at a distance A from the image plane 22 which is greater than 60% of a distance B between the object plane 17 and the image plane 22.

A distance C between the mirrors M4 and M2, i.e. a distance between the last mirror and the antepenultimate mirror along a coordinate perpendicular to the image plane 22, is less than 15% of the distance B between the object plane 17 and the image plane 22.

A distance D between the penultimate mirror M3 in the imaging beam path of the projection optical unit 20b and the image plane 22 can be greater than 20%, greater than 25%, greater than 30%, or greater than 35% of the distance B between the field planes 17, 22.

The projection optical unit 20b once again has a magnification ratio for the imaging of the object field 4 into the image field 21 in the range of between 250 and 500.

Within the imaging beam path in the case of the projection optical unit 20b individual rays have an angle of incidence on the mirror M1 to M4 which are in each case a maximum of 13°. An angle of incidence of the individual rays of the imaging light 3 on the image field 21 is a maximum of 5° in the case of the projection optical unit 20b.

A further embodiment of a projection optical unit 20c, which can be used instead of the above-described projection optical units in the mask inspection system 2a, is explained below with reference to FIGS. 4 and 5. Components and functions corresponding to those which have already been described above with reference to FIGS. 1 to 3 bear the same reference signs, in particular, and will not be discussed in detail again. In FIG. 4, mirrors M2 and M3 are visualized as straight lines. In fact, these mirrors M2 and M3 both are curved mirrors.

An imaging beam path of the projection optical unit 20c corresponds in principle to that of the projection optical unit 20b.

A distance A between the mirror M4 and the image plane 22 is, e.g., approximately 69% of the distance B between the object plane 17 and the image plane 22. A distance C between the mirrors M4 and M2 is, e.g., approximately 13% of the distance B.

In the case of the projection optical unit 20c, the distance D between the penultimate mirror M3 in the imaging beam path and the image plane 22 is, e.g., approximately 35% of the distance B between the field planes 17, 22.

The object field-side numerical aperture NAx is, e.g., 0.27 in the case of the projection optical unit 20c. The object field-side numerical aperture NAy is, e.g., 0.135. The object-side field size is, e.g., 0.74 mm×0.28 mm with a field offset of, e.g., 0.06 mm in y.

The projection optical unit 20c has a magnification ratio of 435.

In the case of the projection optical unit 20c, the distance A has a magnitude such that an imperfection on the reflection surface of the mirror M4 with a typical size of, e.g., 0.16 mm does not result in the shading of a pixel dimension in the image field 21.

No individual ray within the imaging beam path of the projection optical unit 20c has an angle of incidence on one of the mirrors M1 to M4 which is greater than, e.g., 13°.

In the case of the projection optical unit 20c, the imaging light 3 is incident on the image field 21 with an angle of incidence which is less than, e.g., 5°.

In the case of the projection optical unit 20c, a wavefront aberration RMS over the image field 21 is, e.g., at most 20 ma, specifically 10 m, in the case of the exemplary embodiment of the projection optical unit 20c. An image field-side Petzval radius is greater than, e.g., 500 mm in the case of the projection optical unit 20c. An image field-side distortion is, e.g., 1 nm.

The mirrors M1 and M2 each have a boundary of a reflection surface which is used for guiding the imaging or illumination light 3 along the imaging beam path which corresponds to the boundary of the entrance pupil EP. In the case of the mirror M2, a boundary shape is specularly reflected about the xz-plane in comparison with the boundary shape of the entrance pupil EP illustrated in FIG. 5.

Optical design data of the projection optical unit 20c are summarized below in Tables 1a/b. In Table 1a, row “1” refers to a distance between the object plane 17 and the aperture stop 9b. Row “3” refers to the distance between the aperture stop 9b and mirror M1.

The first column of Table 1a indicates the respective optical surface, beginning with the object field 4.

The second column of Table 1a indicates a radius of curvature of the respective optical surface.

The following column of Table 1a indicates a radius of curvature of the sphere fitted to the optical surface.

The fourth column of Table 1a indicates a z-distance relative to the respectively preceding surface.

The fifth column of Table 1a indicates an optical effect of the surface if such an optical effect is present. In the case of the mirrors M1 to M4, this optical effect is “REFL”, i.e. reflective.

The first column of Table 1b indicates a maximum value of a height of incidence (distance perpendicular to the optical axis) of the respective surface description of the optical surface in mm.

The second column of Table 1b indicates a maximum deviation of the respective aspherical optical surface from the best-fitted sphere, once again in mm.

In addition, for the mirror surfaces of the mirrors M1, M2 and M4 the subsequent Table 2 also indicates coefficients K, C₁, C₂ and C₃ in accordance with the following asphere surface formula:

$$p ( h ) = [ ( ( 1 / r ) {n}^{2} ) / ( 1 + SQRT ( 1 - ( 1 + K ) {( 1 / r )}^{2} {h}^{2} ) ) ] + {C}_{1} \cdot {h}^{4} + {C}_{2} \cdot {h}^{6} + {C}_{3} \cdot {h}^{8}$$

In this case, p is the sagittal height, h is the height of incidence, r is the radius of curvature, K is the conic constant and C₁, C₂ and C₃ are the first three even coefficients of the asphere correction polynomial.

The deviation from the best-fitted sphere results from the difference between the sagittal heights in accordance with the surface formula of the asphere and the best-fitted sphere.

Table 1a for FIGS. 4/5

| | | Radius of best- | | |
|---|---|---|---|---|
| | | fitted sphere | Thickness | |
| Optical surface | Radius [mm] | [mm] | [mm] | Effect |
| Object field | Infinite | | 0.000 | |
| 1: | Infinite | | 297.654 | |
| Aperture stop | Infinite | | 0.000 | |
| 3: | Infinite | | 391.216 | |
| M1 | 540.167 | 541.1 | −470.928 | reflective |
| M2 | 51.130 | 51.226 | 598.100 | reflective |
| M3 | −44.815 | −44.815 | −434.431 | reflective |
| M4 | 1174.354 | 1174.824 | 867.233 | reflective |
| Image field | Infinite | | 0.000000 | |

Table 1b for FIGS. 4/5

| | | Max. |
|---|---|---|
| | Max. height of incidence | deviation of asphere |
| Optical surface | [mm] | from sphere [mm] |
| Object field | | |
| 1: | | |
| Aperture stop | 83.5 | |
| 3: | | |
| M1 | 185 | 0.0150 |
| M2 | 11.5 | 0.0007 |
| M3 | 7.7 | 0 |
| M4 | 160 | 0.009 |
| Image field | | |

Table 2 for FIGS. 4/5

| Mirror | K | C₁ | C₂ | C₃ |
|---|---|---|---|---|
| M1 | −0.0572 | 0.000000E+00 | 0.135E−17 | 0.779E−23 |
| M2 | −0.1520 | 0.000000E+00 | 0.360E−10 | 0.202E−13 |
| M4 | −0.6361 | 0.000E+00 | −0.576E−18 | 0.795E−22 |

The values provided in Tables 1a, 1b, and 2 for FIGS. 4/5 are merely examples, other values can also be used depending on the design of the optical system.

The mirrors M1, M2 and M4 are thus embodied as aspheres in the case of the projection optical unit 20c. The mirror M3 is a spherical mirror.

In FIG. 5, an obscuration effect of the mirror M2 in relation to the entrance pupil EP is also illustrated at OBS. The mirror M2 is embodied such that the obscuration OBS does not overlap the semicircular entrance pupil EP.

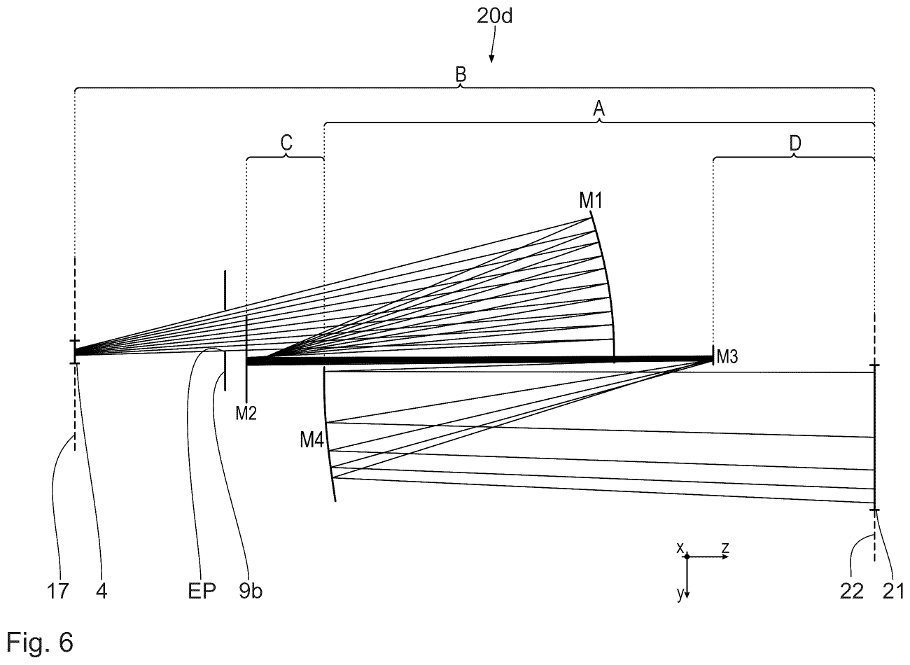

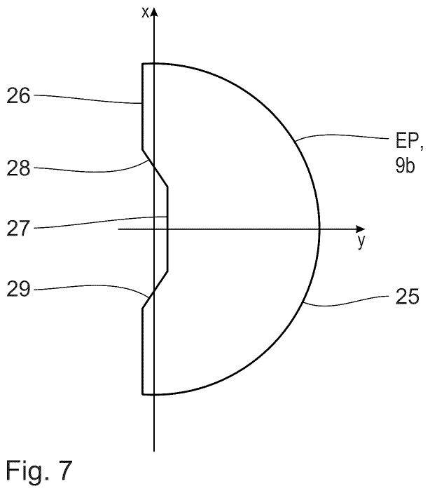

A further embodiment of a projection optical unit 20d, which can be used instead of the above-described projection optical units in the mask inspection system 2a, is explained below with reference to FIGS. 6 and 7. Components and functions corresponding to those which have already been described above with reference to FIGS. 1 to 5 bear the same reference signs, in particular, and will not be discussed in detail again. In FIG. 4, mirrors M2 and M3 are visualized as straight lines. In fact, these mirrors M2 and M3 both are curved mirrors.

The object field-side numerical aperture NAx is, e.g., 0.25 in the case of the projection optical unit 20d. The object field-side numerical aperture NAy is, e.g., 0.125. The object-side field size is, e.g., 0.56 mm×0.36 mm with a field offset of, e.g., 0.06 mm in y.

The projection optical unit 20d, too, has four mirrors M1 to M4. In the case of the projection optical unit 20d, in the illustration a beam path is specularly reflected about the xz-plane in comparison with the beam path of the projection optical unit 20c. Otherwise, the beam path within the projection optical unit 20d corresponds in principle to that within the projection optical unit 20c.

The following holds true for the distance ratio A to B in the case of the projection optical unit 20d:
A/B≃69%.

The further distance ratios are:
C/B≃10%
D/B≃20%.

The values 69%, 10%, and 20% are exemplary values for the projection optical unit 20d shown in FIG. 6, other values can also be used.

FIG. 7 shows an edge contour of the entrance pupil EP, which at the same time corresponds to an inner boundary contour of the aperture stop 9b. The entrance pupil EP of the projection optical unit 20d has a boundary shape having a semicircular boundary portion 25 and a diameter boundary portion 26. Along the diameter boundary portion 26, which together with the semicircular boundary portion 25 produces a total boundary of the entrance pupil EP, a cutout portion 27 is present in the boundary of the entrance pupil EP. A central cutout of this cutout portion 27 runs parallel to the diameter boundary portion 26 in a manner offset with respect thereto in the positive y-direction. This central cutout of the cutout portion 27 merges into the diameter boundary portion 26 via two oblique boundary portions 28, 29.

A y-distance between the central cutout portion 27 and the diameter boundary portion 26 is, e.g., less than 15% of a y-extent of the total entrance pupil EP. The total cutout in the diameter boundary portion thus has a negligible area in comparison with the semicircular envelope around the entrance pupil EP and also in comparison with the area of the entrance pupil EP itself.

The cutout portion 27 is attributable to an obscuration of the entrance pupil EP which is caused by the mirror M2 of the projection optical unit 20d. The cutout portion 27 is helpful to define illumination angle conditions in the vicinity of an area of a beam path blocked by the pupil obscuration.

A magnification ratio is, e.g., 435 in the case of the projection optical unit 20d.

A wavefront aberration RMS over the image field 21 is, e.g., 15 mλ in the case of the projection optical unit 20d.

An image field-side Petzval radius is of the order of, e.g., 20.000 mm in the case of the projection optical unit 20d.

Optical design data concerning the projection optical unit 20d are summarized below once again in two tables, the structure of which corresponds to that of the tables for FIGS. 4 and 5, i.e. for the projection optical unit 20c.

Tables 1a/b for FIGS. 6/7

| | | Radius of | | |
|---|---|---|---|---|
| | | best-fitted | Thickness | |
| Optical surface | Radius [mm] | sphere [mm] | [mm] | Effect |
| Object field | Infinite | | 0.000 | |
| 1: | Infinite | | 196.000 | |
| Aperture stop | Infinite | | 0.000 | |
| 3: | Infinite | | 479.56 | |
| M1 | 527.767 | 528.588 | −459.1 | reflective |
| M2 | 50.000 | 50.095 | 584.25 | reflective |
| M3 | 44.030 | 44.03 | −489.63 | reflective |
| M4 | 1263.26 | 1264.587 | 688.9 | reflective |
| Image field | Infinite | | 0.000000 | |

Table 1b for FIGS. 6/7

| | | Max. |
|---|---|---|
| | Max. height of incidence | deviation of asphere |
| Optical surface | [mm] | from sphere [mm] |
| Object field | | |
| 1: | | |
| Aperture stop | | |
| 3: | | |
| M1 | 170 | 0.012 |
| M2 | 10.5 | 0.0006 |
| M3 | 7.6 | 0 |
| M4 | 180 | 0.004 |
| Image field | | |

Table 2 for FIGS. 6/7

| Mirror | K | C₁ | C₂ | C₃ | C₄ |
|---|---|---|---|---|---|
| M1 | −0.0584 | 0.000E+00 | 0.17E−17 | 0.666E−23 | 0 |
| M2 | −0.161 | 0.000E+00 | 0.438E−10 | 0.5450E−14 | 0.642E−17 |
| M4 | −0.205 | 0.000E+00 | −3.1E−18 | 0.5E−22 | −1E−28 |

The values provided in Tables 1a, 1b, and 2 for FIGS. 6/7 are merely examples, other values can also be used depending on the design of the optical system.

The aspherical mirrors of the projection optical unit 20a and also the aspherical mirrors M1, M2 and M4 of the projection optical units 20c and 20d have reflection surfaces which deviate from a spherical shape by at most 25 μm. The small mirrors M2 and M3 in respect of the extension of the reflection surfaces, these mirrors also being referred to as small-area mirrors having a reflection surface diameter of less than 50 mm, deviate from a spherical shape by at most 5 μm. In the case of the projection optical units 20c and 20d, the respectively spherical mirror M3 does not deviate at all from a spherical shape.

An illumination light beam path of the illumination light 3 for illuminating the reticle 18 and an imaging light beam path of the projection optical unit 20a for imaging the object field 4 into the image field 21 cross one another in a crossing region. This crossing region can lie in the region of the entrance pupil plane EP of the projection optical unit 20a. The imaging light beam path here crosses the illumination light beam path between the exit opening 14 and the mirror IL2 of the illumination optical unit 1 and also between the mirrors IL2 and IL3 of the illumination optical unit 1.

The image field 21 is captured by a detection device 23, for example one charge coupled device (CCD) camera or a plurality of CCD cameras. Each CCD camera can include one or more sensor devices, each sensor device can have a plurality of sensing elements or pixels, e.g., an array of sensing elements or pixels. For details of the imaging into the image field, reference is made to U.S. Pat. No. 10,042,248 B2 and the references cited in U.S. Pat. No. 10,042,248 B2. The detection device 23 can also be embodied as a TDI (time delay integration) detection device comprising a plurality of TDI detectors.

The detection device 23 is embodied in spatially resolving fashion. The detection device 23 can comprise sensor pixels having a typical pixel size of at most 20 μm×20 μm. This pixel size can be smaller and can be for example 15 μm×15 μm or else 10 μm×10 μm. A pixel dimension along an image field coordinate x and/or y can be in the range of between 1 μm and 20 μm.

An inspection of a structure on the reticle 18, for example, is possible by use of the mask inspection system 2a.

Although the present invention is defined in the attached claims, it should be understood that the present invention can also be defined in accordance with the following embodiments:

Embodiment 1: Magnifying imaging optical unit (20a; 20b; 20c; 20d) for a metrology system (2a) for examining objects (18),
comprising at most 4 mirrors (M1, M2; M3; M1, M2, M3, M4) which image an object field (4) in an object plane (17) into an image field (21) in an image plane (22) along an imaging beam path,
comprising an entrance pupil (EP) comprising a boundary shape which deviates from an ellipse and the aspect ratio of which is not equal to 1.
   Embodiment 2: Magnifying imaging optical unit according to Embodiment 1, characterized in that the entrance pupil (EP) has a boundary shape which has a semicircular boundary portion (25).
   Embodiment 3: Magnifying imaging optical unit according to Embodiment 2, characterized in that along a diameter boundary portion (26) which together with the semicircular boundary portion (25) produces a total boundary of the entrance pupil (EP), a cutout portion (27) is present in the boundary.
   Embodiment 4: Magnifying imaging optical unit according to any of Embodiments 1 to 3, characterized by at least one mirror (M1; M1, M2) comprising a boundary at the reflection surface which is used for guiding imaging light (3) along the imaging beam path which corresponds to the boundary of the entrance pupil (EP).
   Embodiment 5: Magnifying imaging optical unit (20a; 20b; 20c; 20d) for a metrology system (2a) for examining objects (18),
comprising at most four mirrors (M1, M2, M3; M1, M2, M3, M4) which image an object field (4) in an object plane (17) into an image field (21) in an image plane (22), wherein at least one of the mirrors is a small-area mirror (M2, M3) with a diameter of the reflection surface which is less than 50 mm, wherein the reflection surface of the small-area mirror (M2, M3) deviates from a spherical shape by at most 10 μm.
   Embodiment 6: Magnifying imaging optical unit according to Embodiment 5, characterized in that the reflection surfaces of all the mirrors deviate from a spherical shape by at most 25 μm.
   Embodiment 7: Magnifying imaging optical unit according to any of Embodiments 1 to 6, wherein a last mirror (M3; M4) in the imaging beam path is at a distance from the image plane (22) which is greater than 60% of a distance between the object plane (17) and the image plane (22).
   Embodiment 8: Magnifying imaging optical unit according to any of Embodiments 1 to 7, characterized by a magnification ratio in the range of between 250 and 500.
   Embodiment 9: Magnifying imaging optical unit according to any of Embodiments 1 to 8, characterized in that no individual ray within the imaging beam path has an angle of incidence on one of the mirrors (M1, M2; M1 to M4) which is greater than 14°.
   Embodiment 10: Magnifying imaging optical unit according to any of Embodiments 1 to 9, characterized in that the imaging beam path is embodied in such a way that the imaging light (3) is incident on the image field (21) with an angle of incidence which is less than 5°.
   Embodiment 11: Magnifying imaging optical unit according to any of Embodiments 1 to 10, characterized by a maximum RMS wavefront aberration of 50 mλ.
   Embodiment 12: Magnifying imaging optical unit according to any of Embodiments 1 to 11, characterized in that the reflection surface of at least one of the mirrors deviates from a spherical shape by at least double a used wavelength.
   Embodiment 13: Illumination optical unit (1) for a metrology system (2a) for examining objects (18),
comprising an illumination pupil which is adapted to an entrance pupil (EP) of an imaging optical unit according to any of Embodiments 1 to 12,
wherein the illumination pupil has a boundary shape which deviates from an ellipse and the aspect ratio of which is not equal to 1.
   Embodiment 14: Optical system (2) comprising an imaging optical unit (20a; 20b; 20c; 20d) according to any of Embodiments 1 to 12 and comprising an illumination optical unit (1) for illuminating the object field (4) with illumination light (3).
   Embodiment 15: Optical system (13) comprising an illumination optical unit according to Embodiment 13.
   Embodiment 16: Metrology system (2a)
comprising an optical system according to Embodiment 14 or 15,
comprising a light source (5),
comprising a spatially resolving detection device (22) which captures the image field (21).

A number of implementations have been described. Nevertheless, it will be understood that various modifications may be made. For example, the elements of one or more implementations may be combined, deleted, modified, or supplemented to form further implementations. In addition, other components may be added to, or removed from, the described mask inspection system. The curvatures and positions of the mirrors and aperture stops of the mask inspection system can have values different from the examples described above.

Accordingly, other implementations are within the scope of the following claims.

What is claimed is:

1. A magnifying imaging optical unit for a metrology system for examining objects,
comprising at most 4 mirrors which image an object field in an object plane into an image field in an image plane along an imaging beam path, and
comprising an entrance pupil comprising a boundary shape which deviates from an ellipse and the aspect ratio of which is not equal to 1.

2. The magnifying imaging optical unit of claim 1, wherein the entrance pupil has a boundary shape which has a semicircular boundary portion.

3. The magnifying imaging optical unit of claim 2, wherein along a diameter boundary portion which together with the semicircular boundary portion produces a total boundary of the entrance pupil, a cutout portion is present in the boundary.

4. The magnifying imaging optical unit of claim 1, wherein at least one of the mirrors comprises a boundary at the reflection surface which is used for guiding imaging light along the imaging beam path which corresponds to the boundary of the entrance pupil.

5. A magnifying imaging optical unit for a metrology system for examining objects),
comprising at most four mirrors which image an object field in an object plane into an image field in an image plane, wherein at least one of the mirrors is a small-area mirror with a diameter of the reflection surface which is less than 50 mm, wherein the reflection surface of the small-area mirror deviates from a spherical shape by at most 10 μm.

6. The magnifying imaging optical unit of claim 5, wherein the reflection surfaces of all the mirrors deviate from a spherical shape by at most 25 μm.

7. The magnifying imaging optical unit of claim 1, wherein a last mirror in the imaging beam path is at a distance from the image plane which is greater than 60% of a distance between the object plane and the image plane.

8. The magnifying imaging optical unit of claim 1, comprising a magnification ratio in the range of between 250 and 500.

9. The magnifying imaging optical unit of claim 1, wherein no individual ray within the imaging beam path has an angle of incidence on one of the mirrors which is greater than 14°.

10. The magnifying imaging optical unit of claim 1, wherein the imaging beam path is embodied in such a way that the imaging light is incident on the image field with an angle of incidence which is less than 5°.

11. The magnifying imaging optical unit of claim 1, comprising a maximum RMS wavefront aberration of 50 mλ.

12. The magnifying imaging optical unit of claim 1, wherein the reflection surface of at least one of the mirrors deviates from a spherical shape by at least double a used wavelength.

13. An illumination optical unit for a metrology system for examining objects,
comprising an illumination pupil which is adapted to an entrance pupil of an imaging optical unit according to claim 1, and
wherein the illumination pupil has a boundary shape which deviates from an ellipse and the aspect ratio of which is not equal to 1.

14. An optical system comprising an imaging optical unit according to claim 1 and comprising an illumination optical unit for illuminating the object field with illumination light.

15. An optical system comprising an illumination optical unit according to claim 13.

16. A metrology system
comprising an optical system according to claim 14,
comprising a light source, and
comprising a spatially resolving detection device which captures the image field.

17. The metrology system of claim 16, wherein the optical system comprises an illumination optical unit for a metrology system for examining objects, wherein the illumination optical unit comprises:
an illumination pupil which is adapted to an entrance pupil of a magnifying imaging optical unit for a metrology system for examining objects,
wherein the magnifying imaging optical unit comprises:
at most 4 mirrors which image an object field in an object plane into an image field in an image plane along an imaging beam path, and
an entrance pupil comprising a boundary shape which deviates from an ellipse and the aspect ratio of which is not equal to 1; and
wherein the illumination pupil has a boundary shape which deviates from an ellipse and the aspect ratio of which is not equal to 1.

18. The metrology system of claim 16, wherein the entrance pupil has a boundary shape which has a semicircular boundary portion.

19. The optical system of claim 15, wherein the entrance pupil has a boundary shape which has a semicircular boundary portion.

20. The optical system of claim 14, wherein the entrance pupil has a boundary shape which has a semicircular boundary portion.
